(19) United States
(12) Patent Application Publication
(10) Pub. No.: US 2011/0198749 A1
(43) Pub. Date: Aug. 18, 2011

(54) Semiconductor chip package and method of manufacturing the same

(75) Inventors: Hee Kon Lee, Hwaseong (KR); Ju Pyo Hong, Suwon (KR); Eun Kyung Jeon, Suwon (KR); Seung Wook Park, Suwon (KR); Young Do Kweon, Seoul (KR); Jin Gu Kim, Suwon (KR)

(73) Assignee: Samsung Electro-Mechanics Co., Ltd., Suwon (KR)

(21) Appl. No.: 12/929,783

(22) Filed: Feb. 15, 2011

(30) Foreign Application Priority Data
Feb. 16, 2010 (KR) 10-2010-0013812

(51) Int. Cl. H01L 23/52; H01L 21/56

(52) U.S. Cl. 257/737; 438/127; 257/E23.141; 257/E21.502

(57) ABSTRACT

Provided are a semiconductor chip package and a method of manufacturing the same. The semiconductor chip package includes a semiconductor chip comprising a chip pad, and a rerouting layer disposed on the semiconductor chip and including a metal interconnection electrically connected to the chip pad and a partial oxidation region formed by the oxidation of metal and insulating the metal interconnection.

### CROSS-REFERENCE TO RELATED APPLICATIONS

This application claims the priority of Korean Patent Application No. 10-2010-0013812 filed on Feb. 16, 2010, in the Korean Intellectual Property Office, the disclosure of which is incorporated herein by reference.

### BACKGROUND OF THE INVENTION

1. Field of the Invention

The present invention relates to a semiconductor chip package and a method of manufacturing the same, and more particularly, to a semiconductor chip package achieving high heat dissipation efficiency and high process efficiency, and a method of manufacturing the same.

2. Description of the Related Art

In the semiconductor industry, one of main technology trends involves scaling down semiconductor elements. In line with this trend, semiconductor packages, such as fine pitch ball grid arrays (FBGA) or chip scale packages (CSP), are currently under development in order to implement a plurality of pins within their limited sizes in response to a significant demand for reducing the size of semiconductor packages used for compact computers, portable electronic devices, or the like.

Semiconductor packages, such as FBGAs or CSPs, both of which are currently under development, have physical advantages including small size and light weight. However, this type of semiconductor package has limitations in terms of reliability and price competitiveness as compared to the related art plastic packages. This low price competitiveness is caused by the high unit costs of subsidiary materials and processes consumed in the manufacturing process

Examples of packages developed to overcome the above limitations include so-called wafer level CSPs (WL-CSP) that utilize redistribution or rerouting schemes concerning bonding pads of semiconductor chips formed on a wafer. WL-CSPs including redistributed pads have structural characteristics in that bonding pads, placed on a semiconductor substrate, are electrically connected to redistributed pads having a greater size than the bonding pads directly in a semiconductor-device fabrication process (FAB), and external connection terminals, such as solder balls, are then formed thereon.

### SUMMARY OF THE INVENTION

An aspect of the present invention provides a semiconductor chip package achieving high heat dissipation efficiency and high process efficiency, and a method of manufacturing the same.

According to an aspect of the present invention, there is provided a semiconductor chip package including: a semiconductor chip including a chip pad; and a rerouting layer disposed on the semiconductor chip, and including a metal interconnection electrically connected to the chip pad and a partial oxidation region formed by the oxidation of metal and insulating the metal interconnection.

The rerouting layer may have a multilayer structure and include: a first rerouting layer disposed on the semiconductor chip, and including a first metal interconnection electrically connected to the chip pad and a first partial oxidation region formed by the oxidation of a first metal and insulating the first metal interconnection; and a second rerouting layer disposed on the first rerouting layer and including a second metal interconnection electrically connected to the first metal interconnection and a second partial oxidation region formed by the oxidation of a second metal and insulating the second metal interconnection.

The semiconductor chip package may further include a protruding connection terminal disposed on the metal interconnection.

The rerouting layer may include a metal dummy region for heat dissipation, the metal dummy region being formed of the same metal as that of the metal interconnection.

The semiconductor chip package may further include a heat dissipation metal interconnection disposed in the rerouting layer and connected with the metal dummy region.

The semiconductor chip package may further include a protruding connection terminal disposed on the heat dissipation metal interconnection.

The semiconductor chip package may further include a molding film encompassing the semiconductor chip while exposing the chip pad.

The semiconductor chip package may further include a heat sink mounted on the semiconductor chip and formed on a side opposite to another side on which the rerouting layer is disposed.

According to another aspect of the present invention, there is provided a method of manufacturing a semiconductor chip package, the method including: preparing a semiconductor chip including a chip pad; forming a metal layer on the semiconductor chip; disposing a resist pattern on a region of the metal layer in which a metal interconnection is to be formed; and forming a rerouting layer by subjecting the metal layer to oxidation, the rerouting layer including a metal interconnection electrically connected to the chip pad and a partial oxidation region insulating the metal interconnection.

The oxidation may be carried out by an anodizing process.

The forming of the rerouting layer may include: forming a first metal layer on the semiconductor chip; disposing a resist pattern on a region of the first metal layer in which a first metal interconnection is to be formed; forming a first rerouting layer by subjecting the first metal layer to oxidation, the first rerouting layer including the first metal interconnection electrically connected to the chip pad and a first partial oxidation region insulating the first metal interconnection; forming a second metal layer on the first rerouting layer; disposing a resist pattern on a region of the second metal layer in which a second metal interconnection is to be formed; and forming a second rerouting layer by subjecting the second metal layer to oxidation, the second rerouting layer including the second metal interconnection electrically connected to the first metal interconnection and a second partial oxidation region insulating the second metal interconnection.

The resist pattern may be disposed on a region of the metal layer in which no electrical connection with the chip pad is made, and the oxidation may be carried out to thereby form a metal dummy region.

The resist pattern may be disposed on a region of the metal layer in which a heat dissipation interconnection is to be formed, and the oxidation may be carried out to thereby form the heat dissipation metal interconnection connected to the metal dummy region.

The method may further include forming a molding film encompassing the semiconductor chip while exposing the chip pad.

The method may further include mounting the semiconductor chip on a heat sink.

The method may further include forming a protruding connection terminal connected to the metal interconnection.

### BRIEF DESCRIPTION OF THE DRAWINGS

The above and other aspects, features and other advantages of the present invention will be more clearly understood from the following detailed description taken in conjunction with the accompanying drawings, in which:

FIG. 1A is a schematic plan view illustrating a semiconductor chip package according to an exemplary embodiment of the present invention;

FIG. 1B is a schematic cross-sectional view, taken along line I-I′ of FIG. 1A, illustrating the semiconductor chip package; and

FIGS. 2A through 2I are cross-sectional views illustrating sequential processes associated with a method of manufacturing a semiconductor chip package according to an exemplary embodiment of the present invention.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and sizes of elements may be exaggerated for clarity. Like reference numerals in the drawings denote like elements, and thus their description will be omitted.

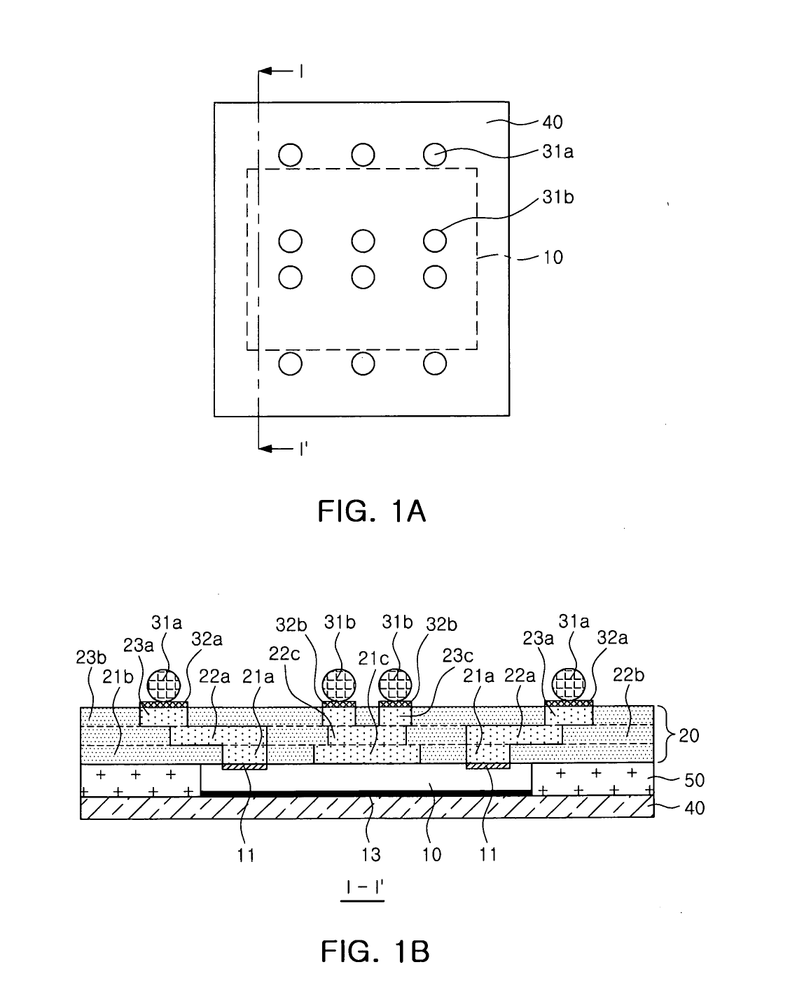

FIG. 1A is a schematic plan view illustrating a semiconductor chip package according to an exemplary embodiment of the present invention. FIG. 1B is a schematic cross-sectional view, taken along line I-I′ of FIG. 1A, illustrating the semiconductor chip package.

Referring to FIGS. 1A and 1B, a semiconductor chip package having chip pads 11, according to an exemplary embodiment of the invention, includes a semiconductor chip 10; and a rerouting layer 20 disposed on the semiconductor chip 10.

The semiconductor chip 10 may include therein a semiconductor element, such as a memory, a logic device, a passive device or the like. The chip pad 11 may be an element to electrically connect the semiconductor device to an external substrate.

As for the semiconductor chip 10, the chip pads 11 may be redistributed as pads (hereinafter, redistributed pads), which are greater than the chip pads 11, by the rerouting layer 20. Thereafter, external connection terminals may be formed on the redistributed pads.

The rerouting layer 20 includes metal interconnections 21a, 22a and 23a electrically connected to the chip pads 11, and partial oxidation regions 21b, 22b and 23b formed by the oxidation of metal forming the metal interconnections 21a, 22a and 23a.

The metal interconnections 21a, 22a and 23a may be formed of oxidizable metal. The oxidizable metal, although not limited thereto, may utilize aluminum (Al), magnesium (Mg) titanium (Ti), zinc (Zn), tantalum (Ta), iron (Fe), nickel (Ni), or an alloy thereof, and may preferably utilize aluminum (Al).

The partial oxidation regions 21b, 22b and 23b may be formed by the oxidation of metal forming the metal interconnections. For example, the partial oxidation regions 21b, 22b and 23b may be anodized films formed by anodizing the metal.

In the case that the metal interconnections 21a, 22a, and 23a are formed of aluminum (Al), the partial oxidation regions 21b, 22b and 23b may be anodized aluminum insulating films (Al×O3).

The rerouting layer 20 is formed by forming a metal layer through deposition or the like and subjecting the metal layer to oxidation. The rerouting layer 20 may have a small thickness and high heat transmission characteristics.

The rerouting layer 20 may have a multilayer structure, and may include a first rerouting layer and a second rerouting layer.

In more detail, the first rerouting layer is formed on the semiconductor chip 20, and may include first metal interconnections 21a electrically connected to the chip pads 11, and a first partial oxidation region 21b formed by oxidizing a first metal. The first metal interconnections 21a are insulated by the first partial oxidation region 21b.

The second rerouting layer is formed on the first rerouting layer, and may include second metal interconnections 22a electrically connected to the first metal interconnections 21a, and a second partial oxidation region 22b formed by oxidizing a second metal. The second metal interconnections 22a are insulated by the second partial oxidation region 22b.

According to this exemplary embodiment, the rerouting layer may have a multilayer structure, and facilitates interlayer connections without forming via holes.

In addition, the first rerouting layer may include a metal dummy region 21c serving for heat dissipation and formed of the same metal as that of the first metal interconnection 21a. The metal dummy region 21c may be formed in a portion of the first rerouting layer in which no electrical connection with the chip pads 11 is formed. The metal dummy region 21c may be formed by interrupting the oxidation of the metal layer when the partial oxidation region is formed. The metal dummy region 21c may further improve the heat dissipation efficiency of the semiconductor chip package.

The second rerouting layer may include a first heat dissipation metal interconnection 22c connected with the metal dummy region 21c.

Furthermore, as shown in the drawings, a third rerouting layer is formed on the second rerouting layer. The third rerouting layer may include third metal interconnections 23a electrically connected to the second metal interconnections 22a, and a third partial oxidation region 23b formed by oxidizing a third metal. The third metal interconnections 23a are insulated by the third partial oxidation region 23b. The third rerouting layer may include second heat dissipation metal interconnections 23c connected to the first heat dissipation metal interconnection 22c.

Furthermore, protruding connection terminals 31a and 31b may be formed on the metal interconnections of the rerouting layer. The protruding connection terminal may be one element that electrically connects the semiconductor chip 10 to an external substrate. Such protruding connection terminals 31a and 31b may be solder balls or bumps.

If the third rerouting layer is provided as shown in the drawings, the protruding connection terminals 31a may be formed on the third metal interconnections 23a, and protruding connection terminals 31b may be formed on the second heat dissipation metal interconnections 23c.

Furthermore, an under bump metallization (UBM) 32a may be interposed between the third metal interconnections 23a and the protruding connection terminals 31a. The UBM 32a may also be interposed between the second heat dissipation metal interconnections 23c and the protruding connection terminals 31b.

The semiconductor chip package according to this exemplary embodiment may include a molding film 50 encompassing the semiconductor chip 10 for the purpose of structural support and electrical isolation. The molding film 50 may be formed of a resin material the thickness of which may be easily controlled. Furthermore, the molding film 50 may utilize a material having a high corrosion resistance with respect to an acidic solution used in an oxidation process.

The molding film 50 may be formed in such a manner as to encompass the semiconductor chip 10 while exposing the chip pads 11 of the semiconductor chip 10. In this case, the molding film 50 may be formed up to the side surface of the semiconductor chip 10 and the active surface of the semiconductor chip 10 on which the chip pads 11 are formed may be opened.

According to this exemplary embodiment, the semiconductor chip 10 may be mounted on a heat sink 40. The semiconductor chip 10 may be mounted on the heat sink 40 by the medium of an adhesive 13, and the molding film 50 may be formed on the heat sink 40.

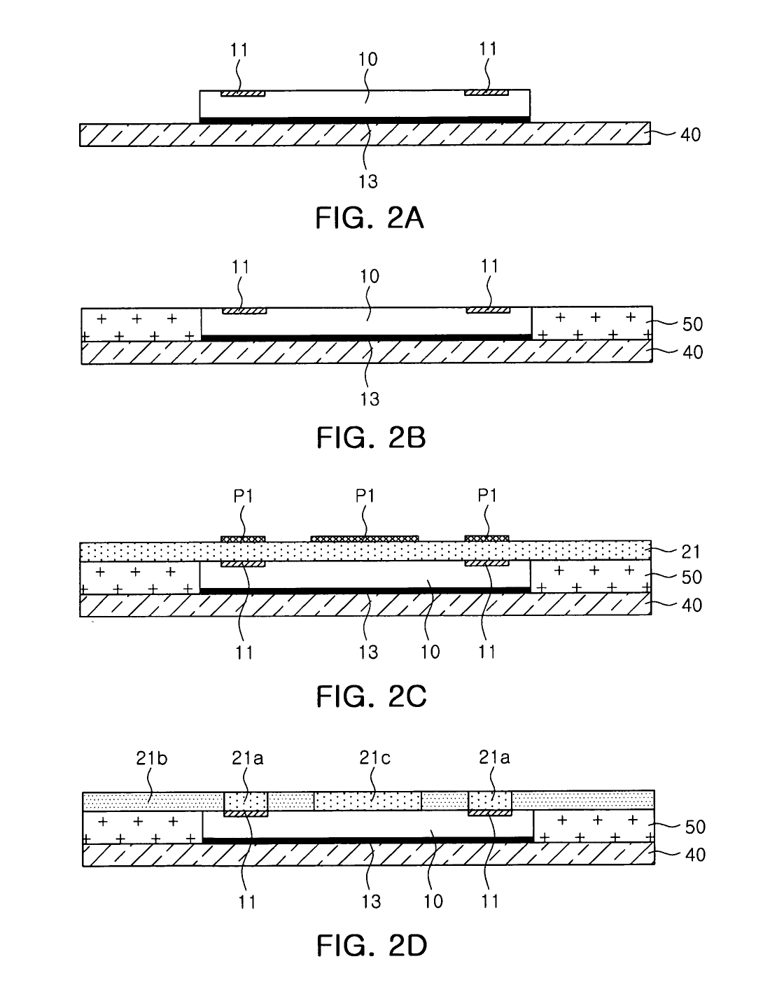

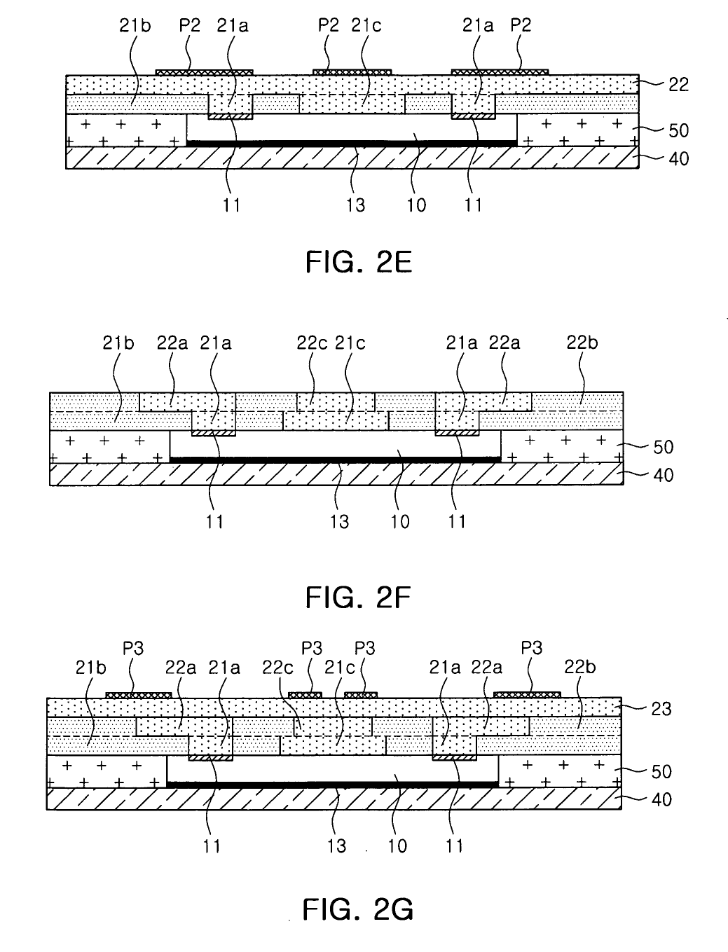

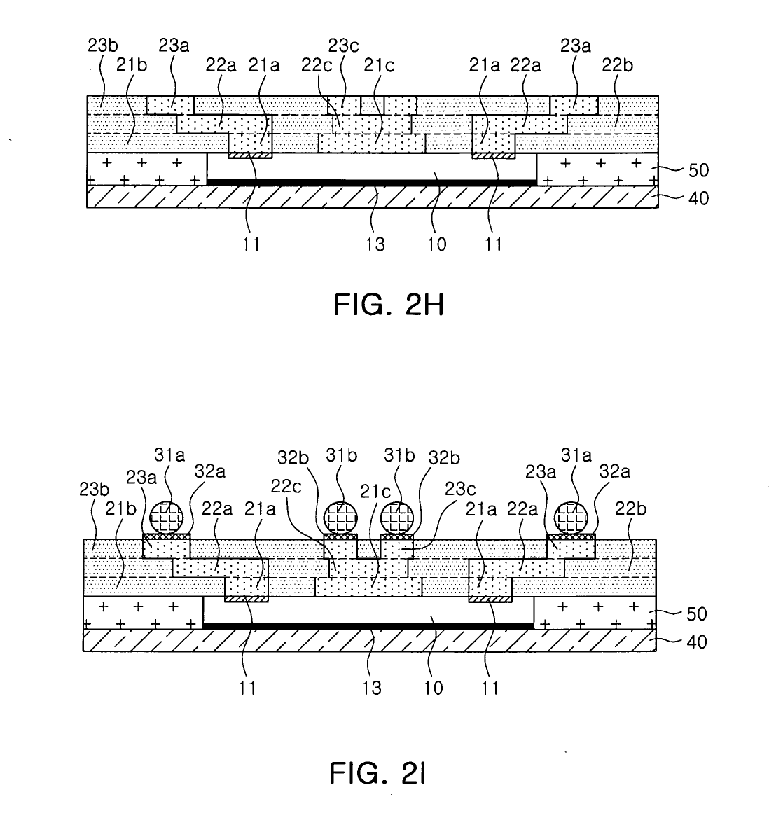

FIGS. 2A through 2I are cross-sectional views illustrating the sequential processes of a method of manufacturing a semiconductor chip package according to an exemplary embodiment of the present invention.

As shown in FIG. 2A, a semiconductor chip 10 having chip pads 11 is provided. The semiconductor chip 10 may be mounted on a heat sink 40 by the medium of an adhesive 13. The semiconductor chip 10 may be loaded, attached to a carrier tape (not shown).

Subsequently, as shown in FIG. 2B, a molding film 50 encompassing the semiconductor chip 10 is formed. The molding film 50 may be formed by using a resin material the thickness of which may be easily controlled. The molding film 50 may utilize a material having a high corrosion resistance with respect to an acidic solution used in an oxidation process.

The molding film 50 may be formed in such a manner as to encompass the semiconductor chip 10 while exposing the chip pads 11. In this case, the molding film 50 may be formed up to the side surface of the semiconductor chip 10, and the active surface of the semiconductor chip 10 on which the chip pads 11 are formed may be exposed.

Subsequently, as shown in FIG. 2C, a first metal layer 21 is formed on the semiconductor chip 10. The first metal layer 21 may be formed to have an even and small thickness by a deposition process. A first metal constituting the first metal layer is not specifically limited if it is oxidizable. For example, the first metal layer 21 may utilize aluminum (Al), magnesium (Mg), titanium (Ti), zinc (Zn), tantalum (Ta), iron (Fe), nickel (Ni) or an alloy thereof. Preferably, the first metal layer 21 may be formed of aluminum (Al).

Thereafter, a resist pattern P1 is disposed on the first metal layer 21, and an oxidation process is performed thereupon. The resist pattern P1 is disposed on a region of the first metal layer 21 in which metal interconnections electrically connected to the chip pads 11 are to be formed.

In more detail, the oxidation process may be carried out by an anodizing process using boric acid, phosphoric acid, sulfuric acid, chromate acid or the like.

Thus, as shown in FIG. 2D, the first metal layer 21 is oxidized except for the portions thereof on which the resist pattern P1 is disposed, thereby forming a first partial oxidation region 21b.

The portions of the first metal layer 21 on which the resist pattern is disposed do not experience oxidation, and form first metal interconnections 21a electrically connected to the chip pads 11. The first metal interconnections 21a are insulated from each other by the first partial oxidation region 21b.

That is, the first metal layer 21 is subjected to the oxidation process to thereby form a first rerouting layer including the first metal interconnections 21a and the first partial oxidation region 21b.

Furthermore, the resist pattern P1 may also be disposed on a region of the first metal layer 21 in which the metal interconnections are not to be formed. Thus, a metal dummy region 21c may be formed in a region in which an electrical connection with the chip pads 11 is not made. Like the metal interconnections, the metal dummy region 21c is a region of the first metal layer 21 which does not undergo oxidation due to the resist pattern.

Thereafter, as shown in FIG. 2E, a second metal layer 22 is formed on the first rerouting layer.

Subsequently, a resist pattern P2 is disposed on the second metal layer 22, and an oxidation process is performed thereupon. The resist pattern P2 is disposed on a region of the second metal layer 22 in which second metal interconnections, electrically connected to the first metal interconnections 21 of the first rerouting layer, are to be formed.

As stated above, the second metal layer 22 may be formed of aluminum (Al). The oxidation process may be carried out by an anodizing process.

As shown in FIG. 2F, the second metal layer 22 is oxidized except for the portions thereof on which the resist pattern is disposed, thereby forming a second partial oxidation region 22b.

The portions of the second metal layer 22 on which the resist pattern P2 is disposed are not oxidized and form second metal interconnections 22a electrically connected to the first metal interconnections 21a. The second metal interconnections 22a are insulated from each other by the second partial oxidation region 22b.

In the above manner, the second metal layer 22, subjected to the oxidation, forms a second rerouting layer including the second metal interconnections 22a and the second partial oxidation region 22b.

Furthermore, the resist pattern P2 may also be disposed on the metal dummy region 21C. Accordingly, a first heat dissipation metal interconnection 22c, connected to the metal dummy region 21c, may be formed.

Subsequently, as shown in FIG. 2G, a third metal layer 23 may be formed on the second rerouting layer. Thereafter, a resist pattern P3 is disposed on the third metal layer 23, and oxidation is carried out upon the third metal layer 23.

As described above, the third metal layer 23 may be formed of aluminum (Al), and the oxidation may be carried out by an anodizing process.

Accordingly, as shown in FIG. 2H, the third metal layer 23 is oxidized except for the portions thereof on which the resist pattern P3 is disposed, thereby forming a third partial oxidation region 23b.

The portions of the third metal layer 23 on which the resist pattern P3 is disposed are not oxidized and form third metal interconnections 23a electrically connected to the second metal interconnections 22a. The third metal interconnections 23a are insulated from each other by the third partial oxidation region 23b.

The third metal layer 23, subjected to the oxidation, forms a third rerouting layer including the third metal interconnections 23a and the third partial oxidation region 23b.

Furthermore, the resist pattern P3 may also be disposed on the first heat dissipation metal interconnection 22c of the second rerouting layer, to thereby form a second heat dissipation metal interconnection connected to the first heat dissipation metal interconnection 22c.

Thereafter, as shown in FIG. 2I, protruding connection terminals 31a may be formed on the third metal interconnections 23a. A UBM 32a may be interposed between the third metal interconnections 23a and the protruding connection terminals 31a.

Furthermore, protruding connection terminals 31b may be formed on the second heat dissipation metal interconnections 23c. A UBM 32b may be interposed between the second heat dissipation metal interconnections 23c and the protruding connection terminals 31b.

As set forth above, in the semiconductor chip package according to exemplary embodiments of the invention, a rerouting layer serves to redistribute chip pads into pads with a grater size, and external connection terminals are formed on the redistributed pads. According to the exemplary embodiments, the rerouting layer includes a thin metal layer and a partial oxidation region formed by oxidizing the metal layer. The rerouting layer contributes to heat transmission efficiency and facilitates an interlayer connection even without a via hole to thereby enhance process efficiency.

While the present invention has been shown and described in connection with the exemplary embodiments, it will be apparent to those skilled in the art that modifications and variations can be made without departing from the spirit and scope of the invention as defined by the appended claims.

What is claimed is:

1. A semiconductor chip package comprising:
a semiconductor chip comprising a chip pad; and
a rerouting layer disposed on the semiconductor chip, and comprising a metal interconnection electrically connected to the chip pad and a partial oxidation region formed by the oxidation of metal and insulating the metal interconnection.

2. The semiconductor chip package of claim 1, wherein the rerouting layer has a multilayer structure, the rerouting layer comprising:
a first rerouting layer disposed on the semiconductor chip and comprising a first metal interconnection electrically connected to the chip pad and a first partial oxidation region formed by the oxidation of a first metal and insulating the first metal interconnection; and
a second rerouting layer disposed on the first rerouting layer and comprising a second metal interconnection electrically connected to the first metal interconnection and a second partial oxidation region formed by the oxidation of a second metal and insulating the second metal interconnection.

3. The semiconductor chip package of claim 1, further comprising a protruding connection terminal disposed on the metal interconnection.

4. The semiconductor chip package of claim 1, wherein the rerouting layer comprises a metal dummy region for heat dissipation, the metal dummy region being formed of the same metal as that of the metal interconnection.

5. The semiconductor chip package of claim 4, further comprising a heat dissipation metal interconnection disposed in the rerouting layer and connected to the metal dummy region.

6. The semiconductor chip package of claim 4, further comprising a protruding connection terminal disposed on the heat dissipation metal interconnection.

7. The semiconductor chip package of claim 1, further comprising a molding film encompassing the semiconductor chip while exposing the chip pad.

8. The semiconductor chip package of claim 1, further comprising a heat sink mounted on the semiconductor chip and formed on a side opposite to another side on which the rerouting layer is disposed.

9. A method of manufacturing a semiconductor chip package, the method comprising:
preparing a semiconductor chip comprising a chip pad;
forming a metal layer on the semiconductor chip;
disposing a resist pattern on a region of the metal layer in which a metal interconnection is to be formed; and
forming a rerouting layer by subjecting the metal layer to oxidation, the rerouting layer comprising a metal interconnection electrically connected to the chip pad and a partial oxidation region insulating the metal interconnection.

10. The method of claim 9, wherein the oxidation is carried out by an anodizing process.

11. The method of claim 9, wherein the forming of the rerouting layer comprises:
forming a first metal layer on the semiconductor chip;
disposing a resist pattern on a region of the first metal layer in which a first metal interconnection is to be formed;
forming a first rerouting layer by subjecting the first metal layer to oxidation, the first rerouting layer comprising the first metal interconnection electrically connected to the chip pad and a first partial oxidation region insulating the first metal interconnection;
forming a second metal layer on the first rerouting layer;
disposing a resist pattern on a region of the second metal layer in which a second metal interconnection is to be formed; and
forming a second rerouting layer by subjecting the second metal layer to oxidation, the second rerouting layer comprising the second metal interconnection electrically connected to the first metal interconnection and a second partial oxidation region insulating the second metal interconnection.

12. The method of claim 9, wherein the resist pattern is disposed on a region of the metal layer in which no electrical connection with the chip pad is made, and the oxidation is carried out to thereby form a metal dummy region.

13. The method of claim 12, wherein the resist pattern is disposed on a region of the metal layer in which a heat dissipation interconnection is to be formed, and the oxidation is carried out to thereby form the heat dissipation metal interconnection connected to the metal dummy region.

14. The method of claim 9, further comprising forming a molding film encompassing the semiconductor chip while exposing the chip pad.

15. The method of claim 9, further comprising mounting the semiconductor chip on a heat sink.

16. The method of claim 9, further comprising forming a protruding connection terminal connected to the metal interconnection.
